(19) United States
(12) Patent Application Publication
(10) Pub. No.: US 2016/0025429 A1
(43) Pub. Date: Jan. 28, 2016

(54) ELECTROACTIVE POLYMER ACTUATED AIR FLOW THERMAL MANAGEMENT MODULE

(71) Applicant: Parker-Hannifin Corporation, Cleveland, OH (US)

(72) Inventors: Arthur H. Muir, San Mateo, CA (US); Michael G. Lipton, Scotts Valley, CA (US); Roger N. Hitchcock, San Leandro, CA (US)

(21) Appl. No.: 14/771,371

(22) PCT Filed: Mar. 14, 2014
(86) PCT No.: PCT/US2014/027226

§ 371 Date: Aug. 28, 2015

Related U.S. Application Data
(60) Provisional application No. 61/791,192, filed on Mar. 15, 2013.

(51) Int. Cl. F28F 13/06; H01L 41/04

(52) U.S. Cl. CPC F28F 13/06; H01L 41/042

(57) ABSTRACT

The disclosure provides a thermal management apparatus. The apparatus includes a housing that defines a first air flow channel and a second air flow channel and an electroactive polymer actuator located within the housing, the electroactive polymer actuator configured to move in response to an activation signal. The electroactive polymer actuator defines a first chamber in fluid communication with the first air flow channel and defines a second chamber in fluid communication with the second air flow channel, the first and second chambers are fluidically isolated from each other. The electroactive polymer actuator is configured to oscillate when excited by the activation signal and eject pulses of air through the first and second air flow channels. An apparatus that includes two electroactive polymer actuators as well as method of generating air flow for thermal management also is disclosed.

### CROSS REFERENCE TO RELATED APPLICATION

This application claims the benefit, under 35 USC §119(e), of U.S. provisional patent application No. 61/791,192, filed Mar. 15, 2013, entitled “EAP AIR MOVING APPLICATION,” the entire disclosure of which is hereby incorporated by reference.

### FIELD OF THE INVENTION

In various embodiments, the present disclosure relates generally to electroactive polymer actuated air flow thermal management modules. More particularly, the present disclosure relates to a single or dual double-diaphragm electroactive polymer actuated air flow thermal management module.

### BACKGROUND OF THE INVENTION

The power and speed of computer components has increased steadily since the introduction of desktop computers decades ago. As with other semiconductor devices, the heat generated by high circuit densities in computer systems and light emitting diode (LED) systems has increased significantly in recent years, such that the thermal management of these devices has become more challenging. Conventional thermal management is often addressed through the use of forced convective air cooling through the use of fans with or without heat sinks. However, fan-based cooling systems are undesirable due to the noise attendant to their use. Moreover, the use of fans also requires relatively large moving parts, and corresponding high power inputs, in order to achieve the desired level of heat transfer. These moving parts are also a potential source of mechanical failure. Furthermore, while fans are adequate for providing global movement of air over electronic devices, they generally provide insufficient localized cooling for adequate heat dissipation of the hot spots that typically exist in a semiconductor device. In addition, the structure, arrangement and mounting mechanisms employed with ruggedized cards frequently interfere with the fluid flow of a thermal management system.

More recently, thermal management systems have been developed which utilize synthetic jet ejectors. These systems are more energy efficient than comparable fan-based systems, and also offer reduced levels of noise and electromagnetic interference. Systems of this type are described in greater detail in U.S. Pat. No. 6,588,497 issued to Glezer et al. The use of synthetic jet ejectors has proven very efficient in providing localized heat dissipation, and hence can be used to address hot spots in semiconductor devices. Synthetic jet ejectors may be used in conjunction with fan-based systems to provide thermal management systems that afford both global and localized heat dissipation.

One example of a thermal management system that utilizes synthetic jet ejectors employs an air-cooled heat transfer module which is based on a ducted heat ejector (DHE) concept. The module uses a thermally conductive, high aspect ratio duct that is thermally coupled to one or more integrated circuit (IC) packages. Heat is removed from the IC packages by thermal conduction into the duct shell, where it is subsequently transferred to the air moving through the duct. The air flow within the duct is induced through internal forced convection by a pair of low form factor synthetic jet ejectors which are integrated into the duct shell. In addition to inducing air flow, the turbulent jet produced by the synthetic jet ejector enables highly efficient convective heat transfer and heat transport at low volume flow rates through small scale motions near the heated surfaces, while also inducing vigorous mixing of the core flow within the duct.

Often times, the synthetic jet ejectors utilize rare earth magnets to move diaphragms to move air, and while such systems represent notable improvements in the art, such rare earth magnets implementations also limit the form factor in which the synthetic jet ejectors can be embodied. Such systems are also limited in the amount of audible noise that is generated, may be quite heavy and relatively bulky.

Accordingly, there still exists a need in the art for a thermal management system that eliminates expensive, limited supply rare earth magnets, and that opens up the possibility of different form factors that are unattainable with current systems. Furthermore, there still exists a need for a thermal management system that can operate while maintaining a very low audible signature that are light weight and can be made smaller than magnet based systems.

### SUMMARY OF THE INVENTION

In one embodiment, the present invention provides a thermal management apparatus comprising a housing that defines a first air flow channel and a second air flow channel; an electroactive polymer actuator located within the housing, the electroactive polymer actuator configured to move in response to an activation signal; wherein the electroactive polymer actuator defines a first chamber in fluid communication with the first air flow channel and defines a second chamber in fluid communication with the second air flow channel, the first and second chambers are fluidically isolated from each other; and wherein the electroactive polymer actuator is configured to oscillate when excited by the activation signal and eject pulses of air through the first and second air flow channels.

In another embodiment, the present invention provides a thermal management apparatus comprising a housing that defines a first air flow channel and a second air flow channel; a first electroactive polymer actuator located within the housing, the first electroactive polymer actuator configured to move in response to a first activation signal; a second electroactive polymer actuator located within the housing, the second electroactive polymer actuator configured to move in response to a second activation signal; wherein the first electroactive polymer actuator defines a first chamber in fluid communication with the first air flow channel and defines a second chamber in fluid communication with the second air flow channel, the first and second chambers are fluidically isolated from each other; wherein the second electroactive polymer actuator defines a third chamber in fluid communication with the first air flow channel, the third chamber is fluidically isolated from the first and second chambers; wherein the first and second electroactive polymer actuators are configured to oscillate when excited by the first and second activation signals and eject pulses of air through the first and second air flow channels.

In yet another embodiment, the present invention provides a method of generating air flow in a thermal management apparatus comprising a housing that defines a first air flow channel and a second air flow channel, an electroactive polymer actuator located within the housing, the electroactive polymer actuator configured to move in response to an activation signal, wherein the electroactive polymer actuator defines a first chamber in fluid communication with the first air flow channel and defines a second chamber in fluid communication with the second air flow channel, the first and second chambers are fluidically isolated from each other, and wherein the electroactive polymer actuator is configured to oscillate when excited by the activation signal and eject pulses of air through the first and second air flow channels, the method comprising applying a first excitation voltage to the electroactive polymer actuator; applying a second excitation voltage to the electroactive polymer actuator that is 180° out of phase with the first excitation voltage; and oscillating the electroactive polymer actuator within the housing in response to the first and second excitation voltages.

In some embodiments, fluids other than air may be used. These fluids may include gases such as nitrogen or argon or fluids. An encapsulating layer may be used to provide protection or electrical isolation of the dielectric film and electrodes of the electroactive polymer actuator from the fluid.

These and other advantages and benefits of the present invention will be apparent from the Detailed Description of the Invention herein below.

### BRIEF DESCRIPTION OF THE FIGURES

The present invention will now be described for purposes of illustration and not limitation in conjunction with the figures, wherein:

FIGS. 1A and 1B illustrate a top perspective view of a transducer before and after application of a voltage in accordance with one embodiment of the present invention; and

FIG. 2 illustrates an exemplary electroactive polymer cartridge in accordance with one embodiment of the present invention.

FIG. 3 is a schematic diagram of a thermal management module comprising a single double-diaphragm electroactive polymer actuator, in accordance with one embodiment of the present invention;

FIG. 4 is a schematic diagram of a thermal management module comprising a dual double-diaphragm electroactive polymer actuator, in accordance with one embodiment of the present invention;

FIG. 5 is a perspective view of thermal management module comprising a dual double-diaphragm electroactive polymer actuator, in accordance with one embodiment of the present invention;

FIG. 6 is a sectional view of the thermal management module shown in FIG. 5 taken along section line 4-4, in accordance with one embodiment of the present invention;

FIG. 7 is a sectional view of the thermal management module shown in FIG. 5 taken along section line 5-5, in accordance with one embodiment of the present invention;

FIG. 8 is a front view of the sectional view of the thermal management module shown in FIG. 5, in accordance with one embodiment of the present invention;

FIG. 9 is a sectional view of the thermal management module shown in FIG. 5 taken along section line 7-7, in accordance with one embodiment of the present invention;

FIG. 10 is a front view of the sectional view of the thermal management module shown in FIG. 9, in accordance with one embodiment of the present invention;

FIG. 11 is a sectional view of the thermal management module shown in FIG. 5, in accordance with one embodiment of the present invention;

FIG. 12 is an exploded view of the thermal management module shown in FIG. 5, in accordance with one embodiment of the present invention;

FIG. 13 is a block diagram of a circuit for driving a dual-diaphragm electroactive polymer actuator in a two-phase mode, in accordance with one embodiment of the present invention;

FIG. 14 illustrates a basic schematic diagram of a phase-splitter circuit, in accordance with one embodiment of the present invention;

FIG. 15 illustrates a basic schematic diagram of a Pull Up/Down Phase-1 circuit or a Pull Up/Down Phase-2 circuit, in accordance with one embodiment of the present invention;

FIG. 16 illustrates a basic schematic of a high voltage generator circuit, in accordance with one embodiment of the present invention;

FIG. 17 illustrates a basic schematic diagram of a drive circuit for driving a double-diaphragm electroactive polymer actuator, in accordance with one embodiment of the present invention;

FIG. 18 is a chart indicating the driving sequence for the six switches in the circuit shown in FIG. 17, in accordance with one embodiment of the present invention;

FIG. 19 illustrates a basic schematic diagram variation of a drive circuit for driving a double-diaphragm electroactive polymer actuator, in accordance with one embodiment of the present invention;

FIG. 20 illustrates a basic schematic diagram variation of a drive circuit for driving a double-diaphragm electroactive polymer actuator, in accordance with one embodiment of the present invention;

FIG. 21 illustrates a basic schematic diagram of a drive circuit variation for driving a double-diaphragm electroactive polymer actuator, in accordance with one embodiment of the present invention;

FIGS. 22A-22C diagrammatically illustrate the geometry and operation of frustum-shaped actuators in accordance with one embodiment of the present invention;

FIG. 23 is a top view of a multi-phase frustum-shaped actuator in accordance with one embodiment of the present invention;

FIG. 24A is an assembly view of another frustum shaped actuator, and FIG. 24B is a side view the same basic actuator with an alternate frame construction in accordance with one embodiment of the present invention;

FIG. 25 is a sectional perspective view of a parallel-stacked type of frustum transducer in accordance with one embodiment of the present invention;

FIG. 26 is a side-section view showing an optional output shaft arrangement with a frustum type transducer in accordance with one embodiment of the present invention;

FIG. 27 is a side-section vie of an alternate, inverted frustum transducer configuration in accordance with one embodiment of the present invention; and

FIG. 28 is a sectional perspective view of a coil spring-biased single frustum transducer in accordance with one embodiment of the present invention.

### DETAILED DESCRIPTION OF THE INVENTION

Examples of electroactive polymer devices, their applications, and methods of manufacturing are described, for example, in U.S. Pat. Nos. 7,394,282; 7,378,783; 7,368,862; 7,362,032; 7,320,457; 7,259,503; 7,233,097; 7,224,106; 7,211,937; 7,199,501; 7,166,953; 7,064,472; 7,062,055; 7,052,594; 7,049,732; 7,034,432; 6,940,221; 6,911,764; 6,891,317; 6,882,086; 6,876,135; 6,812,624; 6,809,462; 6,806,621; 6,781,284; 6,768,246; 6,707,236; 6,664,718; 6,628,040; 6,586,859; 6,583,533; 6,545,384; 6,543,110; 6,376,971; 6,343,129; 7,952,261; 7,911,761; 7,492,076; 7,761,981; 7,521,847; 7,608,989; 7,626,319; 7,915,789; 7,750,532; 7,436,099; 7,199,501; 7,521,840; 7,595,580; 7,567,681; 7,595,580; 7,608,989; 7,626,319; 7,750,532; 7,761,981; 7,911,761; 7,915,789; 7,952,261; 8,183,739; 8,222,799; 8,248,750, and in U.S. Patent Application Publication Nos.: 2007/0200457; 2007/0230222; 2011/0128239; 2012/0126959; 2012/0126667; 2012/0206248; 2013/0002587; 2013/0194082; and in PCT Publication Nos.: WO/2011/097020; WO/2012/099850; WO/2012/099854; WO/2012/118916; WO/20121120009; WO/2011/22438; WO/2012/122440; WO/2012/122440; WO/2012/129357; WO/2012/136503; WO/2012/148644; WO/2012/156423; WO/2012/173669; WO/2012/175533; WO/2013/037508; WO/2013/049485; WO/2013/059560, WO/2013/059562; WO/2013/103470; WO/2013/142552; WO/2013/148641; WO/2013/155377; WO/2013/192143; WO/2014/006005; WO/2014/028819; WO/2014/028822; WO/2014/028825; the entirety of each of which is incorporated herein by reference.

In one embodiment, the present invention provides a thermal management system comprising a single double-diaphragm electroactive polymer actuator. The oscillating electroactive polymer actuator moves air to cool various electronic systems, subsystems, and/or components. In other embodiments, the thermal management system comprises a dual double-diaphragm electroactive polymer actuator, which oscillates to move air. The double-diaphragm electroactive polymer actuator systems are suspended within a housing and are driven at a tuned resonance, 180° out of phase, to move air in and out of the housing through air channels. The resonance frequency may preferably be chosen to minimize audible noise and maximize displacement of the oscillating double-diaphragm. In one example, the resonance frequency may preferably be selected to be approximately 60 Hz. Each diaphragm comprises an electroactive polymer film, a portion of Which is sandwiched between at least one pair of opposing compliant electrodes. An electrical field imposed across the electrodes causes the dielectric electroactive polymer film to thin (decrease in thickness) and expand in area.

A single or dual double-diaphragm comprises two diaphragms, placed back to back (i.e., oriented adjacent to each other), connected in the center with each diaphragm biased away from its mate. In the dual double-diaphragm device, one of the pair may be set on the top of the device (i.e., at one end) and one at the bottom (i.e., at the opposite end). Masses may be affixed to a portion of the diaphragm sets (preferably the center) to provide greater motion at resonance and to lower their resonant frequency and thereby reduce generation of undesired audio artifacts.

The diaphragms may preferably be connected so that the chambers created by the first (outer) and second (inner) surfaces of the diaphragm pairs do not directly communicate with each other, rather the first (outer) and second (inner) surfaces of the diaphragm sets form independent air plenums. This configuration creates a biphasic pumping action in which driving the actuators 180° out of phase with each other creates maximum air displacement on each stroke.

By employing the electroactive polymer actuators in the diaphragm configuration, the thermal management system may be made to operate without the use of rare earth magnets thereby saving cost, reducing weight, and increasing the recyclability of the product at end of life. Also, as electroactive polymer actuators may be made through a printed process, this approach offers the possibility of implementing the thermal management system in a variety of different form factors. Further, electroactive polymer technology may provide a thermal management system that generates less audible noise than conventional systems as the Q factor in the electroactive polymer system is low and the inherent mass is low, allowing the operating parameters to be tuned across a wide range.

Before explaining the embodiments of the inventive electroactive polymer based thermal management system in detail, it should be noted that the disclosed embodiments are not limited in application or use to the details of construction and arrangement of parts illustrated in the accompanying drawings and description. The disclosed embodiments may be implemented or incorporated in other embodiments, variations and modifications, and may be practiced or carried out in various ways. They may be used with fluids other than air, such as inert gases and liquids.

Further, unless otherwise indicated, the terms and expressions employed herein have been chosen for the purpose of describing the embodiments for illustrative purposes and for the convenience of the reader and are not intended for the purposes of limiting any of the embodiments to the particular ones disclosed. It should be understood that any one or more of the disclosed embodiments, expressions of embodiments, and examples may be combined with any one or more of the other disclosed embodiments, expressions of embodiments, and examples, without limitation. Thus, the combination of an element disclosed in one embodiment and an element disclosed in another embodiment is considered to be within the scope of the present disclosure and appended claims.

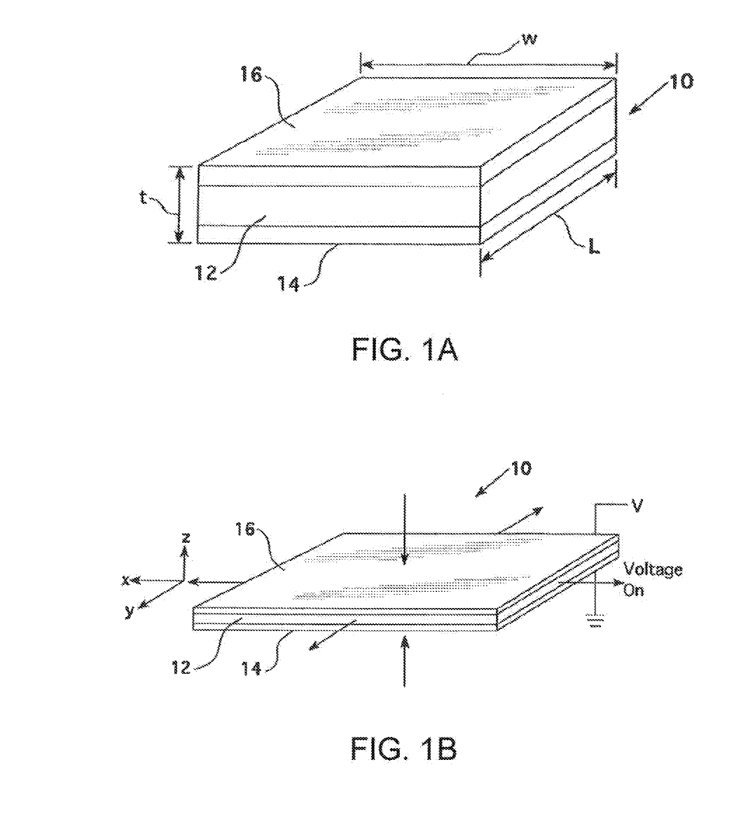

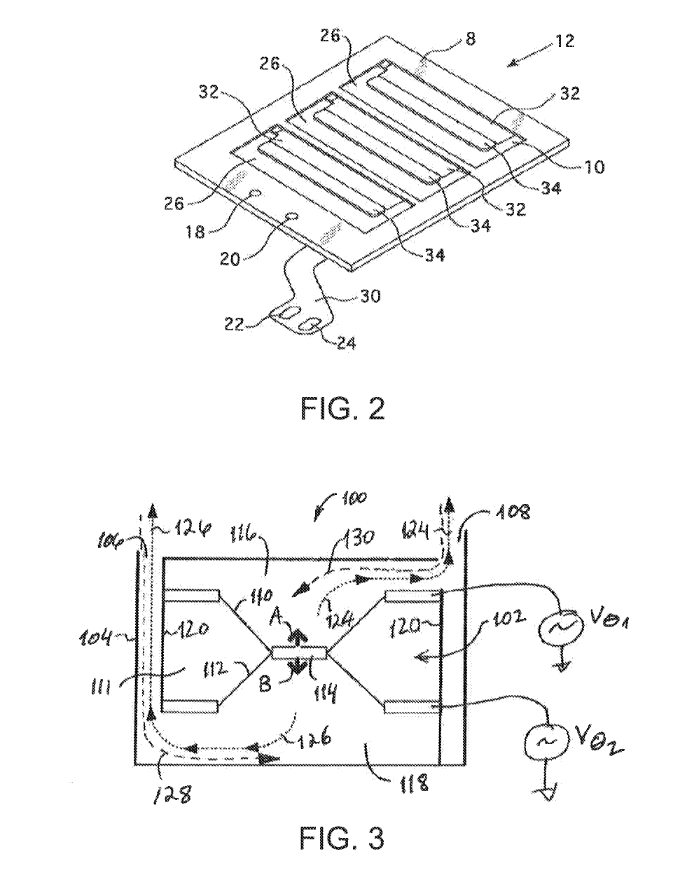

FIGS. 1A, 1B and 2 provide a brief description of electroactive polymer structures, which may be employed to fabricate the single and dual double-diaphragms described above. Accordingly, the description now turns to FIGS. 1A, 1B and 2, which illustrate an example of an electroactive polymer film or membrane 10 structure. A thin elastomeric dielectric film or layer 12 is sandwiched between compliant or stretchable electrode plates or layers 14 and 16, thereby forming a capacitive structure or film. The length “L” and width “w” of the dielectric layer, as well as that of the composite structure, are much greater than its thickness “t”. Preferably, the dielectric layer has a thickness in the range from about 10 μm to about 100 μm, with the total thickness of the structure in the range from about 15 μm to about 10 cm. Additionally, it is desirable to select the elastic modulus, thickness, and/or the geometry of electrodes 14, 16 such that the additional stiffness they contribute to the actuator is preferably less than the stiffness of the dielectric layer 12, which has a relatively low modulus of elasticity, i.e., less than about 100 MPa and more preferably less than about 10 MPa, but is likely thicker than each of the electrodes. Electrodes suitable for use with these compliant capacitive structures are those capable of withstanding cyclic strains greater than about 1% without failure due to mechanical fatigue.

As shown in FIG. 1B, when a voltage is applied across the electrodes, the unlike charges in the two electrodes 14, 16 are attracted to each other and these electrostatic attractive forces compress the dielectric film 12 (along the Z-axis). The dielectric film 12 is thereby caused to deflect with a change in electric field. As electrodes 14, 16 are compliant, they change shape with dielectric layer 12. In the context of the present disclosure, “deflection” refers to any displacement, expansion, contraction, torsion, linear or area strain, or any other deformation of a portion of dielectric film 12. Depending on the architecture, e.g., a frame, in which capacitive structure 10 is employed (collectively referred to as a “transducer”), this deflection may be used to produce mechanical work. Various different transducer architectures are disclosed and described in the above-identified patent references.

With a voltage applied, the transducer film 10 continues to deflect until mechanical forces balance the electrostatic forces driving the deflection. The mechanical forces include elastic restoring threes of the dielectric layer 12, the compliance or stretching of the electrodes 14, 16 and any external resistance provided by a device and/or load coupled to transducer 10. The resultant deflection of the transducer 10 as a result of the applied voltage may also depend on a number of other factors such as the dielectric constant of the elastomeric material and its size and stiffness. Removal of the voltage difference and the induced charge causes the reverse effects.

In some cases, the electrodes 14 and 16 may cover a limited portion of dielectric film 12 relative to the total area of the film. This may be done to prevent electrical breakdown around the edge of the dielectric or achieve customized deflections in certain portions thereof. Dielectric material outside an active area (the latter being a portion of the dielectric material having sufficient electrostatic force to enable deflection of that portion) may be caused to act as an external spring force on the active area during deflection. More specifically, material outside the active area may resist or enhance active area deflection by its contraction or expansion.

The dielectric film 12 may be pre-strained. The pre-strain improves conversion between electrical and mechanical energy, i.e., the pre-strain allows the dielectric film 12 to deflect more and provide greater mechanical work. Pre-strain of a film may be described as the change in dimension in a direction after pre-straining relative to the dimension in that direction before pre-straining. The pre-strain may include elastic deformation of the dielectric film and be formed, for example, by stretching the film in tension and fixing one or more of the edges while stretched. The pre-strain may be imposed at the boundaries of the film or for only a portion of the film and may be implemented by using a rigid frame or by stiffening a portion of the film.

The transducer structure of FIGS. 1A and 1B and other similar compliant structures and the details of their constructs are more fully described in many of the patents and publications referenced herein.

FIG. 2 illustrates an exemplary electroactive polymer cartridge 12 having an electroactive polymer transducer film 26 placed between rigid frame 8 where the electroactive polymer film 26 is exposed in openings of the frame 8. The exposed portion of the film 26 includes two working pairs of thin elastic electrodes 32 on either side of the cartridge 12 where the electrodes 32 sandwich or surround the exposed portion of the film 26. The electroactive polymer film 26 can have any number of configurations. However, in one example, the electroactive polymer film 26 comprises a thin layer of elastomeric dielectric polymer (e.g., made of acrylate, silicone, urethane, thermoplastic elastomer, hydrocarbon rubber, fluoroelastomer, copolymer elastomer, or the like).

When a voltage difference is applied across the oppositely-charged electrodes 32 of each working pair (i.e., across paired electrodes that are on either side of the film 26), the opposed electrodes attract each other thereby compressing the dielectric polymer layer 26 therebetween. The area between opposed electrodes is considered the active area. As the electrodes are pulled closer together, the dielectric polymer 26 becomes thinner (i.e., the Z-axis component contracts) as it expands in the planar directions (i.e., the X- and Y-axes components expand) (See FIG. 1B for axis references). Furthermore, in variations where the electrodes contain conductive particles, like charges distributed across each electrode may cause conductive particles embedded within that electrode to repel one another, thereby contributing to the expansion of the elastic electrodes and dielectric films. In alternate variations, electrodes do not contain conductive particles (e.g., textured sputtered metal films). The dielectric layer 26 is thereby caused to deflect with a change in electric field. As the electrode material is also compliant, the electrode layers change shape along with dielectric layer 26.

As stated herein, deflection refers to any displacement, expansion, contraction, torsion, linear or area strain, or any other deformation of a portion of dielectric layer 26. This deflection may be used to produce mechanical work. As shown in FIG. 2, the dielectric layer 26 can also include one or more mechanical output bars 34. The bars 34 can optionally provide attachment points for either an inertial mass (as described below) or for direct coupling to a substrate in the electronic media device.

In fabricating a transducer, an elastic film 26 can be stretched and held in a pre-strained condition usually by a rigid frame 8. In those variations employing a four-sided frame, the film can be stretched bi-axially. It has been observed that pre-strain improves the dielectric strength of the polymer layer 26, thereby enabling the use of higher electric fields and improving conversion between electrical and mechanical energy, i.e., the pre-strain allows the film to deflect more and provide greater mechanical work. Preferably, the electrode material is applied after pre-straining the polymer layer, but may be applied beforehand. The two electrodes provided on the same side of layer 26, referred to herein as same-side electrode pairs, i.e., electrodes on the top side of dielectric layer 26 and electrodes on a bottom side of dielectric layer 26, can be electrically isolated from each other. The opposed electrodes on the opposite sides of the polymer layer form two sets of working electrode pairs, i.e., electrodes spaced by the electroactive polymer film 26 form one working electrode pair and electrodes surrounding the adjacent exposed electroactive polymer film 26 form another working electrode pair. Each same-side electrode pair can have the same polarity, whereas the polarity of the electrodes of each working electrode pair is opposite each other. Each electrode has an electrical contact portion configured for electrical connection to a voltage source.

In this variation, the electrodes 32 are connected to a voltage source via a flex connector 30 having leads 22, 24 that can be connected to the opposing poles of the voltage source. The cartridge 12 also includes conductive vias 18, 20. The conductive vias 18, 20 can provide a means to electrically couple the electrodes 8 with a respective lead 22 or 24 depending upon the polarity of the electrodes.

The cartridge 12 illustrated in FIG. 2 shows a 3-bar actuator configuration. However, the devices and processes described herein are not limited to any particular configuration, unless specifically claimed. Preferably, the number of the bars 34 depends on the active area desired for the intended application. The total amount of active area, e.g., the total amount of area between electrodes, can be varied depending on the mass that the actuator is trying to move and the desired frequency of movement. In one example, selection of the number of bars is determined by first assessing the size of the object to be moved, and then the mass of the object is determined. The actuator design may be obtained by configuring a design that will move that object at the desired frequency range. Clearly, any number of actuator designs is within the scope of the disclosure.

An electroactive polymer actuator for use in the processes and devices described herein can then be formed in a number of different ways. For example, the electroactive polymer can be formed by stacking a number of cartridges 12 together, having a single cartridge with multiple layers, or having multiple cartridges with multiple layers. Manufacturing and yield considerations may favor stacking single cartridges together to form the electroactive polymer actuator. In doing so, electrical connectivity between cartridges can be maintained by electrically coupling the vias 18, 20 together so that adjacent cartridges are coupled to the same voltage source or power supply.

FIG. 3 is a schematic diagram of a thermal management module 100 comprising a single double-diaphragm electroactive polymer actuator 102, in accordance with one embodiment of the present invention. The thermal management module 100 comprises a housing 104 that defines a first air flow channel 108 and second air flow channel 106. The single double-diaphragm electroactive polymer actuator 102 comprises a first diaphragm 110 and a second diaphragm 112 placed back to back (i.e., oriented adjacent to each other), connected at a center portion thereof with each diaphragm 110, 112 biased away from its mate. A mass 114 may be affixed to the center portion of the first and second diaphragms 110, 112 to provide greater motion at resonance and to lower their resonant frequency to reduce generation of undesired audio artifacts. Each diaphragm 110, 112 comprises an electroactive polymer film configured to move in response to an activation signal being applied to the electroactive polymer film, as described in connection with FIGS. 1A, 1B and 2.

The first and second diaphragms 110, 112 are located within an internal wall 120 defined by the housing 104. The first and second diaphragms 110, 112 are connected to define a first chamber 116 and a second chamber 118, wherein the first chamber 116 is in fluid communication with the first air flow channel 108, the second chamber 118 is in fluid communication with the second air flow channel 106, and the first and second chambers 116, 118 are fluidically isolated such that they do not communicate directly with each other. Accordingly, the first and second chambers 116, 118 created by the first (outer) surfaces of the diaphragm pairs 110, 112 do not directly communicate with each other, and rather the first (outer) surfaces of the diaphragms 110, 112 form independent air plenums. This configuration creates a bi-phasic pumping action whereby driving the actuators 180° out of phase with each other creates maximum air displacement on each stroke. Second (inner) surfaces of each diaphragm 110, 112 also form an isolated chamber 111 that is not in fluid communication with either the first chamber 116 or the second chamber 118.

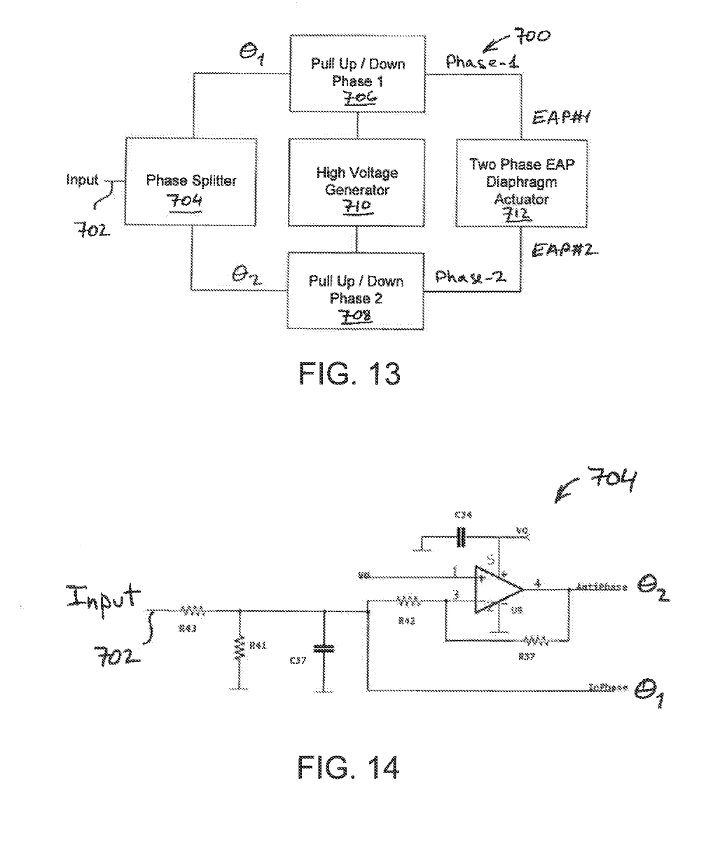

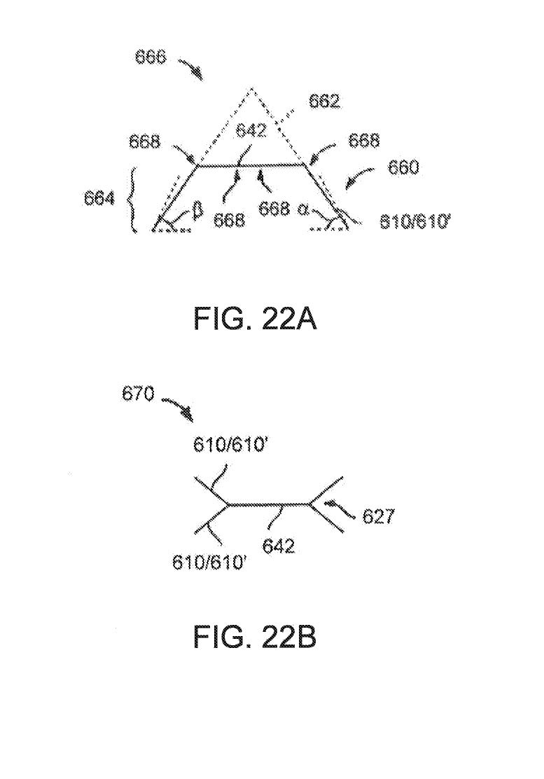

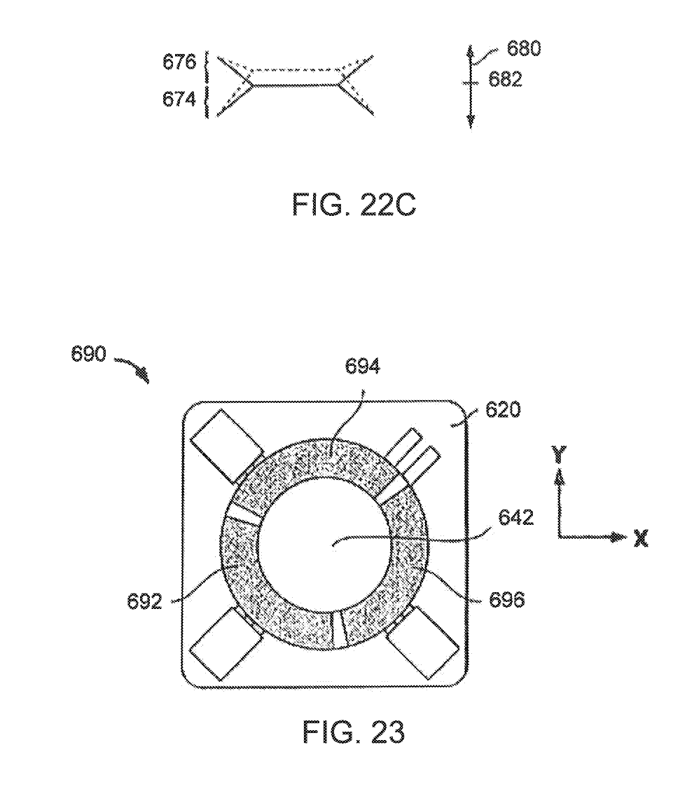

The single double-diaphragm electroactive polymer actuator 102 is driven by alternating high voltage electrical signals that are out of phase relative to each other to cause the single double-diaphragm electroactive polymer actuator 102 to oscillate. Schematically the drive signals are represented by V_{θ1} and V_{θ2}. Although, generally V_{θ1} and V_{θ2} are 180° out of phase, relative phase angle may be selected to suit a particular application. For a detailed description of the operation of the double-diaphragm electroactive polymer actuator 102, please see the description associated with FIGS. 22-28. A detailed description of various circuit configurations that may be employed to drive the double-diaphragm electroactive polymer actuator 102 are described hereinbelow in connection with FIGS. 13-21. The circuit is most useful when the load, in this case the two-phase actuators, is capacitive in nature but has a relatively high ESR (equivalent series resistance).

With reference now to FIG. 3, as the single double-diaphragm electroactive polymer actuator 102 is driven by the alternating high voltage electrical signals, the single double-diaphragm electroactive polymer actuator 102 oscillates in the direction indicated by arrows A and B. The oscillating electroactive polymer actuator 102 moves air contained in the chambers 116, 118 to the first and second air flow channels 108, 106 to cool various electronic systems, subsystems, and/or components. The single double-diaphragm electroactive polymer actuator 102 is suspended within the housing 104 and is driven at a tuned resonance, 180° out of phase, for example, to move air in and out of the housing 104 through the first and second air flow channels 108, 106. The resonance frequency may preferably be chosen to minimize audible noise and maximize displacement of the oscillating double-diaphragm. In one example, the resonance frequency may preferably be selected to be approximately 60 Hz.

As the dual-diaphragm 102 is driven in direction A, a pulse of air 124 is ejected out of the first chamber 116 through the first air flow channel 108 and a pulse of ambient air 128 is drawn into the second chamber 118 through the second air flow channel 106. As the dual-diaphragm 102 is driven in direction B, a pulse of air 126 is ejected out of the second chamber 118 through the second air flow channel 106 and a pulse of ambient air 130 is drawn into the first chamber 116 through the first air flow channel 108. In other embodiments, the thermal management system comprises a dual double-diaphragm electroactive polymer actuator, which oscillates to move air.

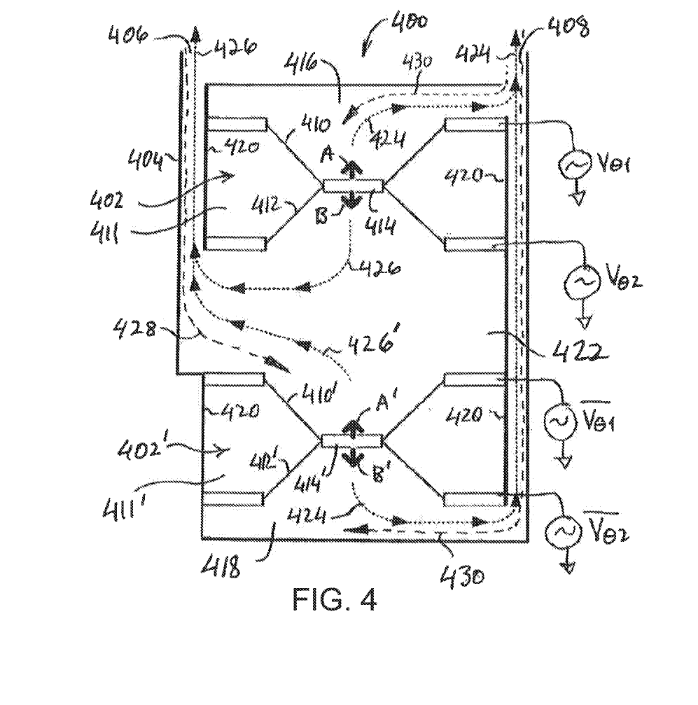

FIG. 4 is a schematic diagram of a thermal management module 400 comprising dual double-diaphragm electroactive polymer actuators 402, 402′, in accordance with one embodiment of the present invention. The thermal management module 400 comprises a housing 404 that defines a second air flow channel 406 and first air flow channel 408. The first (upper) double-diaphragm electroactive polymer actuator 402 comprises a first diaphragm 410 and a second diaphragm 412 placed back to back (i.e., oriented adjacent to each other), connected at a center portion with each diaphragm 410, 411 biased away from its mate. A mass 414 may preferably be affixed to the center portion of the first and second diaphragms 410, 412 to provide greater motion at resonance and to lower their resonant frequency to reduce generation of undesired audio artifacts. Each diaphragm 410, 412 comprises an electroactive polymer film configured to move in response to an activation signal being applied to the electroactive polymer film, as described in connection with FIGS. 1A, 1B and 2.

The second (lower) double-diaphragm electroactive polymer actuator 402′ comprises a first diaphragm 410′ and a second diaphragm 412′ placed back to back (i.e., oriented adjacent to each other), connected at a center portion with each diaphragm biased away from its mate. A mass 414′ is affixed to the center portion of the first and second diaphragms 410′, 412′ to provide greater motion at resonance and to lower their resonant frequency to reduce generation of undesired audio artifacts. Each diaphragm 410′, 412′ comprises an electroactive polymer film configured to move in response to an activation signal being applied to the electroactive polymer film, as described in connection with FIGS. 1A, 1B and 2.

The first and second diaphragms 410, 412 of the first (upper) double-diaphragm electroactive polymer actuator 402 are located within an internal wall 420 defined by the housing 404. The first and second diaphragms 410, 412 are connected to define a first chamber 416 and a second chamber 422, wherein the first chamber 416 is in fluid communication with the first air flow channel 408, the second chamber 422 is in fluid communication with the second air flow channel 406, and the first and second chambers 416, 422 are fluidically isolated such that they do not communicate directly with each other. Accordingly, the first and second chambers 416, 422 created by the first (outer) surfaces of the diaphragm pairs 410, 412 do not directly communicate with each other, and rather the first (outer) surfaces of the diaphragms 410, 422 form independent air plenums. This configuration creates a bi-phasic pumping action in which driving the actuators 180° out of phase with each other creates maximum air displacement on each stroke. Second (inner) surfaces of each diaphragm 410, 412 also form an isolated chamber 411 that is not in fluid communication with either the first chamber 416 or the second chamber 422.

The first and second diaphragms 410′, 412′ of the second (lower) double-diaphragm electroactive polymer actuator 402′ are located within an internal wall 420 defined by the housing 404. The first and second diaphragms 410′, 412′ are connected to define a third chamber 418 and that is in fluid communication with the first air flow channel 408 and is fluidically isolated form the first and second chambers 416, 422 such that they do not communicate directly with each other. Accordingly, the first, second, and third chambers 416, 422, 418 created by the first (outer) surfaces of the diaphragm pairs 410, 412 and 410′, 412′ do not directly communicate with each other, and rather the first (outer) surfaces of the diaphragms 410, 412 and 410′, 412′ form three independent air plenums. This configuration creates a bi-phasic pumping action in which driving the actuators 180° out of phase with each other creates maximum air displacement on each stroke. Second (inner) surfaces of each diaphragm 410, 412 and 410′, 412′ also form an isolated chamber 411′ that is not in fluid communication with either the first, second, or third chamber 416, 422, 418.

The first (upper) and second (lower) double-diaphragm electroactive polymer actuators 402, 402′ are each driven by alternating high voltage electrical signals that are out of phase relative to each other to cause the first (upper) actuator 402 and the second (lower) actuator 402′ to oscillate. Schematically the drive signals are represented by V_{θ1} and V_{θ2}, for the first (upper) actuator 402 and V̅_̅{̅θ̅1̅}̅ and V̅_̅{̅θ̅2̅}̅ for the second (lower) actuator 402′. Although, preferably V_{θ1} and V_{θ2} and V̅_̅{̅θ̅1̅}̅ and V̅_̅{̅θ̅2̅}̅ are 180° out of phase, relative phase angle may be selected to suit a particular application. For a detailed description of the operation of the double-diaphragm electroactive polymer actuators 402, 402′ please refer to the description associated with FIGS. 22-28. A detailed description of various circuit configurations that may be employed to drive the double-diaphragm electroactive polymer actuator 102 are described hereinbelow in connection with FIGS. 13-21.

With reference to FIG. 4, as the dual double-diaphragm electroactive polymer actuator thermal management module 400 is driven by the alternating high voltage electrical signals, the first (upper) double-diaphragm electroactive polymer actuator 402 oscillates in the direction indicated by arrows A and B and the second (lower) dual double-diaphragm electroactive polymer actuator 402′ oscillates in the direction indicated by arrows A′ and B′. The oscillating actuators 402, 402′ move air contained in the chambers 416, 422, and 418 to the air flow channels 406, 408 to cool various electronic systems, subsystems, and/or components. The actuators 402, 402′ are suspended within the housing 404 and are driven at tuned resonances, 180° out of phase, for example, to move air in and out of the housing 404 through the first and first air flow channels 408, 406. The resonance frequency may preferably be chosen to minimize audible noise and maximize displacement of the oscillating double-diaphragm. In one example, the resonance frequency may preferably be selected to be approximately 60 Hz.

As the first (upper) dual-diaphragm electroactive polymer actuator 402 is driven in direction A, the second (lower) dual double-diaphragm electroactive polymer actuator 402′ is driven in direction B′ and a pulse of air 424 is ejected from the first and third chambers 416, 418 through the first air flow channel 408 and a pulse of ambient air 428 is drawn into the second chamber 422 through the first air flow channel 408. As the first (upper) dual-diaphragm 402 is driven in direction B, the second (lower) dual double-diaphragm electroactive polymer actuator 402′ is driven in direction A′ and a pulse of air 426′ is ejected from the second chamber 422 through the first air flow channel 408 and a pulse of ambient air 430 is drawn into the first and third chambers 416, 418 through the first air flow channel 408.

Thus, in operation either the single 102 or dual 402, 402′ double-diaphragm electroactive polymer actuator air flow modules create turbulent, pulsating air-jets that can be directed precisely to locations where thermal management is needed. For example, this may include integrated circuits, light emitting diodes, or any electronic components for heat dissipation and cooling in a highly reliable, flexible form-factor, low cost, and low audible noise implementation.

As airflow is produced by the oscillating diaphragms, 102, 402, 402′, e.g., as the electroactive polymer diaphragms 102, 402, 402′ move up and down (or side to side) in response to the excitation voltage, pulses of air are ejected or pushed out of the air flow channels 106, 108, 406, 408 and injected or drawn in therefrom. The pulses of air are violently ejected and propelled a significant distance away from the air flow channel 106, 108, 406, 408 outlets with such a velocity that a secondary flow is generated as the surrounding air is entrained due to the primary high momentum pulse. This secondary entrainment is responsible for up to ten times the air flow output by the airflow channels 106, 108, 406, 408. As the initial pulse of air is ejected away from the thermal management modules 100, 400, the next pulse of cool air is pulled in and it is done at much lower velocity. The module relies entirely on the ambient air. The air flow is unsteady and turbulent with a series of vortex rings, which results in much higher heat transfer coefficients and therefore, lower airflows are needed to cool the same dissipated power. As the ejected air starts to cool the surface of the heat sink or electronic component, the pulse of air warms up and carries the heat away.

The electroactive polymer based air flow thermal management modules 100, 400 yield a higher effective heat transfer at low-volume flow rates as compared to conventional air movers. Thus, the thermal management modules 100, 400 provide increased thermal efficiency as a result of the turbulence created by the high velocity pulsed air flow. The pulsating nature increases the airflow mixing between the boundary layer and mean flow. The self-induced entrained air flow moves the heated air out of the system. The thermal management modules 100, 400 may be tailored to the air flow needs of any system. Multiple hot spots may be cooled without heat sinks as the thermal management modules 100, 400 place the cooling directly where it is needed without complicated ducting. Heat sinks may be cooled much more effectively by providing uniform flow across the entire heat sink.

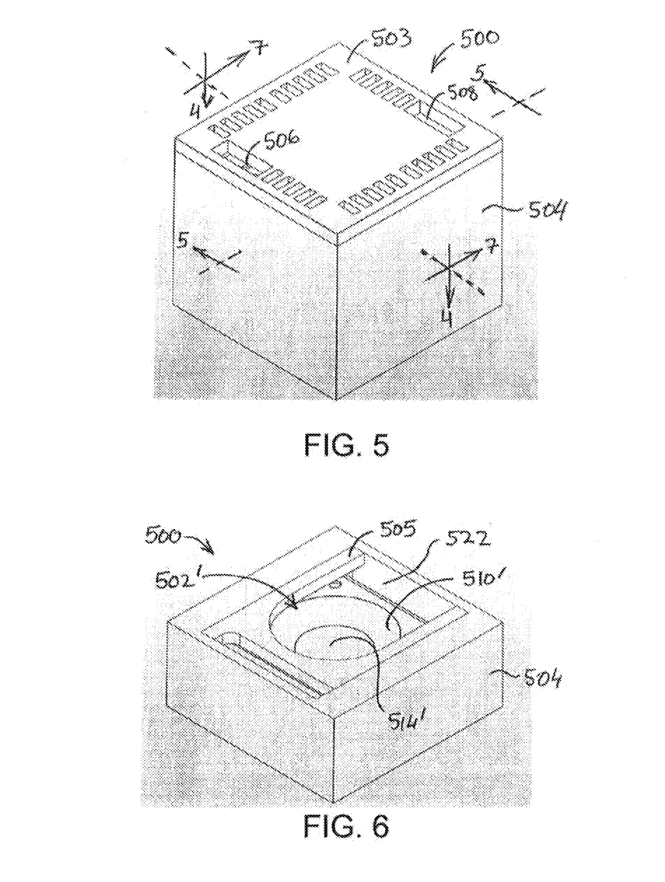

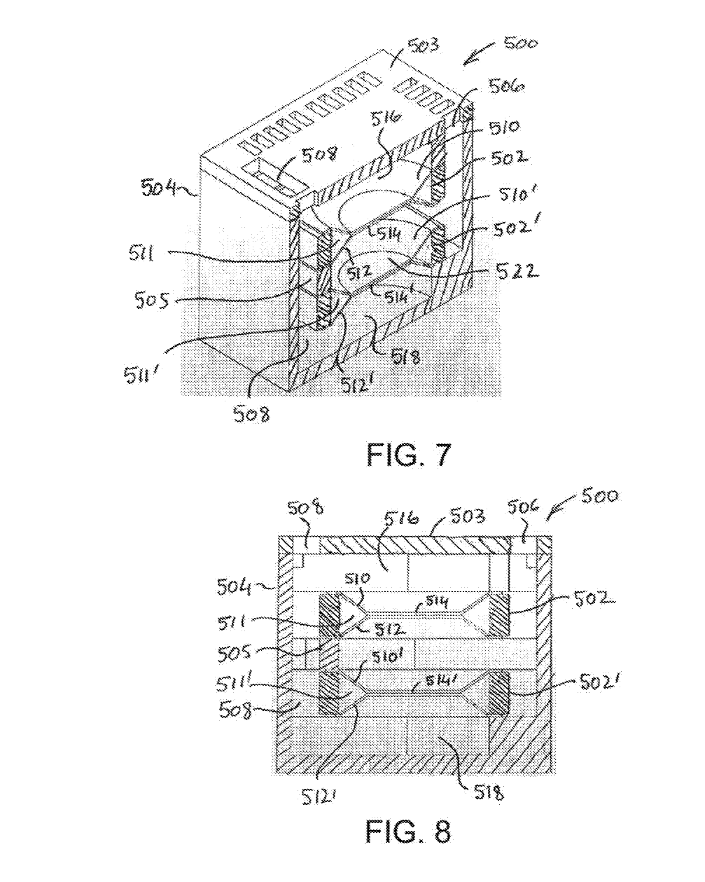

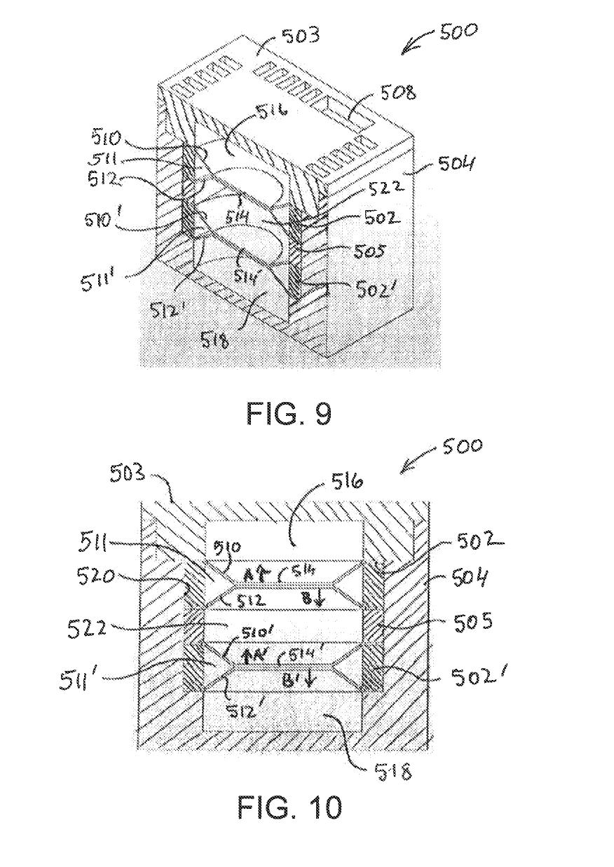

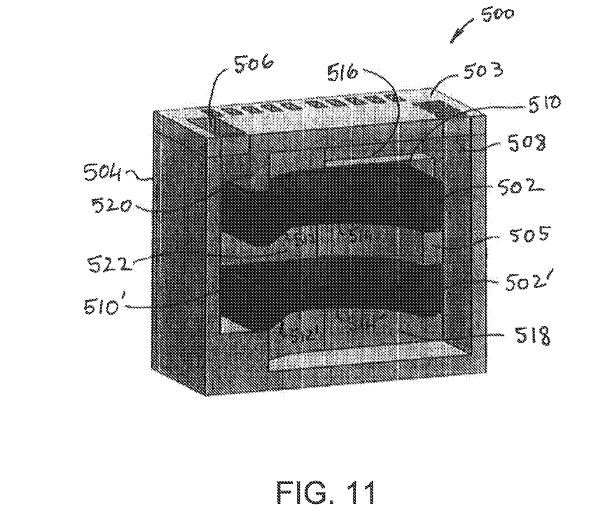

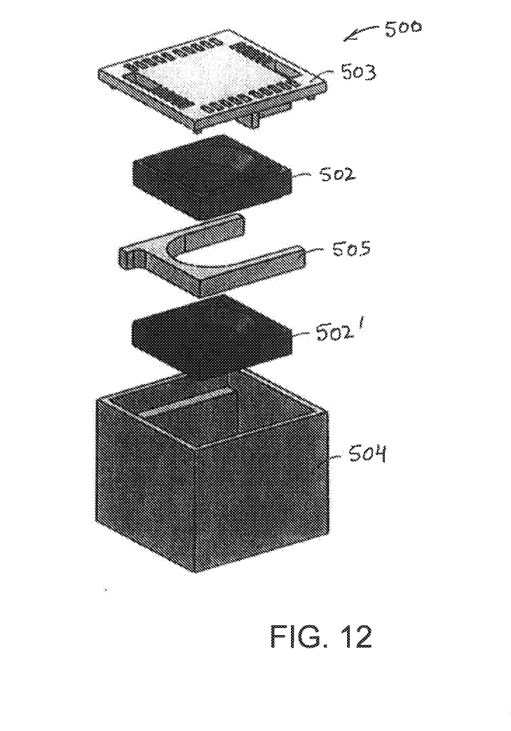

Having described schematically the operation of single and dual double-diaphragm electroactive polymer actuator modules 100, 400, the description now turns to FIGS. 5-12, which describe one embodiment of a dual double-diaphragm electroactive polymer actuator 500. Accordingly, FIG. 7 is a perspective view of a dual double-diaphragm electroactive polymer actuator module 500, in accordance with one embodiment of the present invention. The thermal management module 500 comprises a housing 504 and a lid 503 that defines a second air flow channel 506 and a first air flow channel 508. A spacer 505 supports the two double-diaphragm electroactive polymer actuators 502, 502′ to define a chamber 522 therebetween.

The first (upper) double-diaphragm electroactive polymer actuator 502 comprises a first diaphragm 510 and a second diaphragm 512 placed back to back (i.e., oriented adjacent to each other), connected at a center portion with each diaphragm biased away from its mate. A mass 514 is affixed to the center portion of the first and second diaphragms 510, 512 to provide greater motion at resonance and to lower their resonant frequency to reduce generation of undesired audio artifacts. Each diaphragm 510, 512 comprises an electroactive polymer film configured to move in response to an activation signal being applied to the electroactive polymer film, as described in connection with FIGS. 1A, 1B and 2.

The second (lower) dual double-diaphragm electroactive polymer actuator 502′ comprises a first diaphragm 510′ and a second diaphragm 512′ placed back to back (i.e., oriented adjacent to each other), connected at a center portion with each diaphragm biased away from its mate. A mass 514′ may preferably be affixed to the center portion of the first and second diaphragms 510′, 512′ to provide greater motion at resonance and to lower their resonant frequency to reduce generation of undesired audio artifacts. Each diaphragm 510′, 512′ comprises an electroactive polymer film configured to move in response to an activation signal being applied to the electroactive polymer film, as described in connection with FIGS. 1A, 1B and 2.

The first and second diaphragms 510, 512 of the first (upper) double-diaphragm electroactive polymer actuator 502 are located inside an internal wall 520 defined by the housing 504. The first and second diaphragms 510, 512 are connected to define a first chamber 516 and a second chamber 522, wherein the first chamber 516 is in fluid communication with the first air flow channel 508, the second chamber 522 is in fluid communication with the second air flow channel 506, and the first and second chambers 516, 522 are fluidically isolated such that they do not communicate directly with each other. Accordingly, the first and second chambers 516, 522 created by the first (outer) surfaces of the diaphragm pairs 510, 512 do not directly communicate with each other, and rather the first (outer) surfaces of the diaphragms 510, 522 form independent air plenums. This configuration creates a bi-phasic pumping action in which driving the actuators 180° out of phase with each other creates maximum air displacement on each stroke. Second (inner) surfaces of each diaphragm 510, 512 also form an isolated chamber 511 that is not in fluid communication with either the first chamber 516 or the second chamber 522.

The first and second diaphragms 510′, 512′ of the second (lower) double-diaphragm electroactive polymer actuator 502′ are located inside an internal wall 520 defined by the housing 504. The first and second diaphragms 510′, 512′ are connected to define a third chamber 418 and that is in fluid communication with the first air flow channel 508 and is fluidically isolated from the first and second chambers 516, 522 such that they do not communicate directly with each other. Accordingly, the first, second, and third chambers 516, 522, 518 created by the first (outer) surfaces of the diaphragm pairs 510, 512 and 510′, 512′ do not directly communicate with each other, and rather the first (outer) surfaces of the diaphragms 510, 512 and 510′, 512′ form three independent air plenums. This configuration creates a bi-phasic pumping action in which driving the actuators 180° out of phase with each other creates maximum air displacement on each stroke. Second (inner) surfaces of each diaphragm 510, 512 and 510′, 512′ also form an isolated chamber 511′ that is not in fluid communication with either the first, second, or third chamber 516, 522, 518.

The first (upper) and second (lower) double-diaphragm electroactive polymer actuators 502, 502′ are each driven by alternating high voltage electrical signals that are out of phase relative to each other to cause the first (upper) actuator 502 and the second (lower) actuator 402′ to oscillate. Schematically, as shown in FIG. 4, the drive signals are represented by V_{θ1} and V_{θ2}, for the first (upper) actuator 502 and V̅_̅{̅θ̅1̅}̅ and V̅_̅{̅θ̅2̅}̅ for the second (lower) actuator 502′. Although, preferably V_{θ1} and V_{θ2} and V̅_̅{̅θ̅1̅}̅ and V̅_̅{̅θ̅2̅}̅ are 180° out of phase, relative phase angle may be selected to suit a particular application. For a detailed description of the operation of the double-diaphragm electroactive polymer actuators 502, 502′ please see the description associated with FIGS. 22-28. A detailed description of various circuit configurations that may be employed to drive the double-diaphragm electroactive polymer actuator 102 are described hereinbelow in connection with FIGS. 13-21.

With reference now to FIGS. 7-12, as the dual double-diaphragm electroactive polymer actuator thermal management module 500 is driven by the alternating high voltage electrical signals, the first (upper) double-diaphragm electroactive polymer actuator 502 oscillates in the direction indicated by arrows A and B and the second (lower) dual double-diaphragm electroactive polymer actuator 502′ oscillates in the direction indicated by arrows A′ and B′ as shown in FIG. 10. The oscillating actuators 502, 502′ move air contained in the chambers 516, 522, and 518 to the air flow channels 506, 508 to cool various electronic systems, subsystems, and/or components. The actuators 502, 502′ are suspended within the housing 504 and are driven at tuned resonances, 180° out of phase, for example, to move air in and out of the housing 504 through the first and first air flow channels 508, 506. The resonance frequency may preferably be chosen to minimize audible noise and maximize displacement of the oscillating double-diaphragm. In one example, the resonance frequency may preferably be selected to be approximately 60 Hz.

As the first (upper) dual-diaphragm electroactive polymer actuator 502 is driven in direction A, the second (lower) dual double-diaphragm electroactive polymer actuator 502′ is driven in direction B′ and a pulse of air is ejected from the first and third chambers 516, 518 through the first air flow channel 508 and a pulse of ambient air is drawn into the second chamber 522 through the second (lower) air flow channel 506. As the first (upper) dual-diaphragm 502 is driven in direction B, the bottom dual double-diaphragm electroactive polymer actuator 502′ is driven in direction A′ and a pulse of air is ejected from the second chamber 522 through the second air flow channel 506 and a pulse of ambient air is drawn into the first and third chambers 516, 518 through the first air flow channel 508.

When powering electroactive polymer actuator devices significant reactive power is required. Electroactive polymer devices are capacitive by design and require high voltages to actuate. Much of the electrical energy used to actuate the device is not used to provide mechanical energy. If some of this electrical energy can be recovered an overall improvement in efficiency could be realized. Accordingly, in one embodiment, the present invention provides an electrical circuit (power modulator) that employs electrical energy transferring between two electroactive polymer devices (two phase) to improve the electrical efficiency of the electrical circuit.

FIG. 13 is a block diagram of a circuit 700 for driving a dual-diaphragm electroactive polymer actuator in a two-phase mode, in accordance with one embodiment of the present invention. A voltage input signal 702 is applied to a phase splitter 704. The phase splitter 704 splits the input voltage signal 702 into two signals, an Inphase θ₁ signal and an Antiphase θ₂ signal 180° out of phase relative to each other. The InPhase θ₁ signal is applied to a First Pull/Up Down circuit 706 and the Antiphase θ₂ signal is applied to a second Pull/Up Down circuit 708. A high voltage generator 710 generates a high voltage suitable for driving the dual double electroactive polymer actuator 712. The output of the first Pull/Up Down circuit 706 Phase-1 is applied to the first electroactive polymer actuator (EAP #1) and the output of the Second Pull/Up Down circuit 708 Phase-2 is applied to the second electroactive polymer actuator (EAP #2) of the double electroactive polymer actuator 712, where the Phase-1 and Phase-2 signals are 180° out of phase relative to each other.

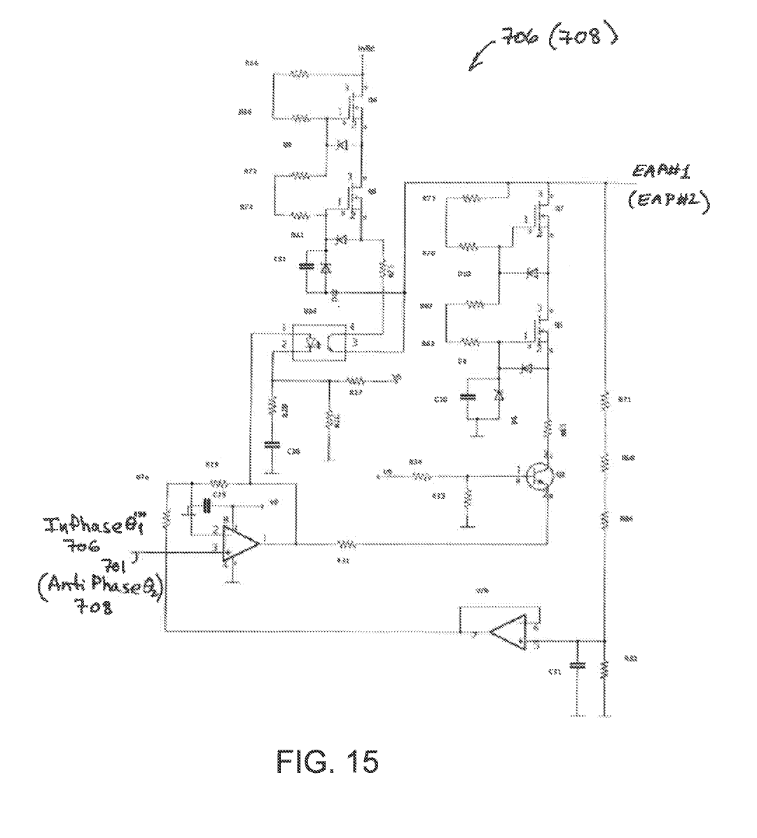

FIG. 14 illustrates a basic schematic diagram of a phase-splitter circuit 702, in accordance with one embodiment of the present invention. The phase-splitter 702 circuit splits the input signal into an Inphase θ₁ signal and an Antiphase θ₂ signal. The input signal is the Inphase θ₁ signal. The Antiphase θ₂ signal is generated by inverting the input Inphase θ₁ signal with inverting amplifier U9. The output of the amplifier U9 is the Antiphase θ₂ signal. The InPhase θ₁ and Antiphase θ₂ signals are applied to the input of the Pull Up/Down Phase-1 circuit 706 or a Pull Up/Down Phase-2 circuit 708 summarized in FIG. 13 and described in more detail in connection with FIG. 15.

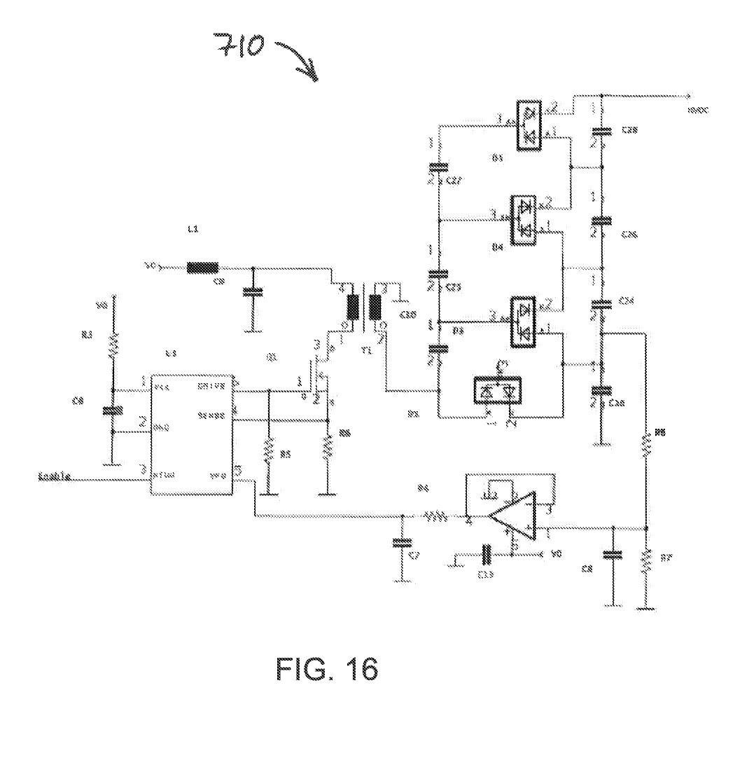

FIG. 15 illustrates a basic schematic diagram of a Pull Up/Down Phase-1 circuit 706 or a Pull Up/Down Phase-2 circuit 708, in accordance with one embodiment of the present invention. Two of these circuits 706, 708 are employed to drive the double-diaphragm electroactive polymer actuator. Only one circuit is shown for convenience and brevity of disclosure. The Inphase θ₁ signal 706 (or Antiphase θ₂ signal 708) from the corresponding output of the phase-splitter circuit 704 is received at an input 701 of amplifier U7a. The high voltage necessary to drive the electroactive polymer is applied at HVDC. The high voltage is received from the high voltage generator circuit 710 described in FIGS. 13 and 16. The high voltage HVDC is coupled to the electroactive polymers' (EAP #1) and (EAP #2) output when the opto-coupler circuit U14 is activated through transistors Q4, Q6 and transistor Q2 is turned off. The electroactive polymer is discharged through transistors Q5, Q7 when transistor Q2 is turned on.

FIG. 16 illustrates a basic schematic of a high voltage generator circuit 710, in accordance with one embodiment of the present invention. An Enable signal applied to U3 initiates the voltage step up process. The drive signal is switched to the transformer T1 primary by transistor Q1. The secondary of the transformer T1 is tied to the voltage multiplier ladder network of capacitors C18, C10, C24, C25, C26, C27, C28 and diodes D1, D3, D4, and D5. The high voltage output HVDC is applied to the Pull Up/Down Phase-1 706 and the Phase-2 708 circuits shown in FIG. 15 to drive the electroactive polymers (EAP #1) and (EAP #2).

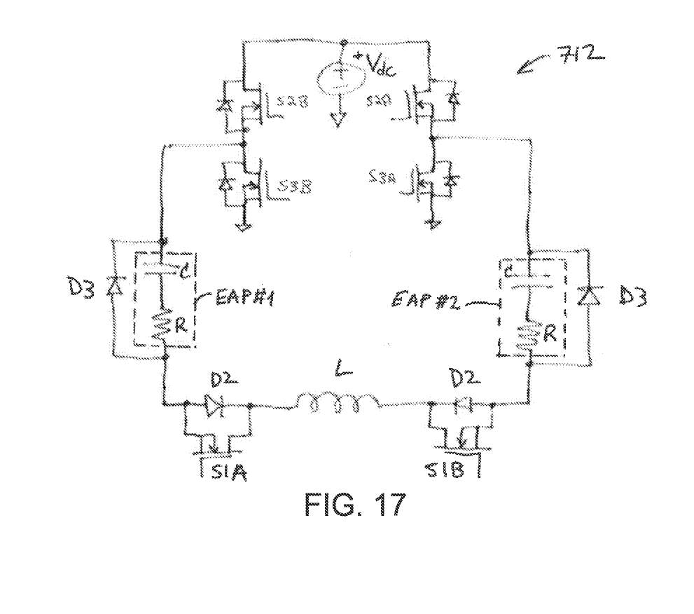

FIG. 17 illustrates a basic schematic diagram of a drive circuit 712 for driving a double-diaphragm electroactive polymer actuator, in accordance with one embodiment of the present invention. The circuit 712 is connected to the first electroactive polymer (EAP #1) and the second electroactive polymer (EAP #2). The circuit 712 uses six transistor switches S1A, S2A, S3A, S1B, S2B, S3B, a direct current power supply V_{dc}, an inductor L and diodes D2, D3 to perform the electrical energy transfer (power modulation) between two electroactive polymer devices. To activate the circuit 712, first the DC power supply V_{dc} is turned on. Switches S3A and S3B are closed and switches S1A, S1B, S2A and S2B are opened. For the first energy transfer cycle, switch S3A is opened and switches S1A and S2A are closed. Energy is transferred from the de power supply V_{dc} to the electroactive polymer (EAP #2) through switch S2A, diode D2, inductor L, switch S1A, and diode D3. When the energy transfer is complete switches S1A and S2A are opened and switch S3A is closed. The time it takes to transfer the energy is dependent on the capacitance of the electroactive polymer (EAP #2) and inductor L. For the next energy transfer cycle, switch 5313 is opened and switches S1B and S2B are closed. Energy from the dc power supply V_{dc} and the energy in electroactive polymer (EAP #2) is transferred to electroactive polymer (EAP #1) through switch S2B, diode D2, inductor L, switch S1B, and diode D3.

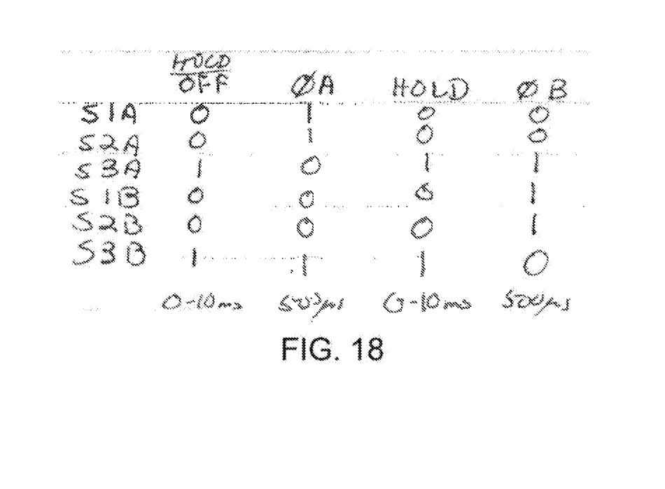

FIG. 18 is a chart indicating the driving sequence for the six switches in the circuit 712 shown in FIG. 17, in accordance with one embodiment of the present invention. As shown, during the holding periods switches S3A and S3B are turned on and the remaining switches S1A, S2A, S1B, S2B are turned off. During the phase θ_{A}, switches S1A, S2A, and S3B are turned on and switched S3A, S1B, and S2B are turned off. During the phase θ_{B}, switches S1A, S2A, and S3B are turned off and switched S3A, S1B, and S2B are turned on. Thus, phases θ_{A} and θ_{B} are 180° out of phase.

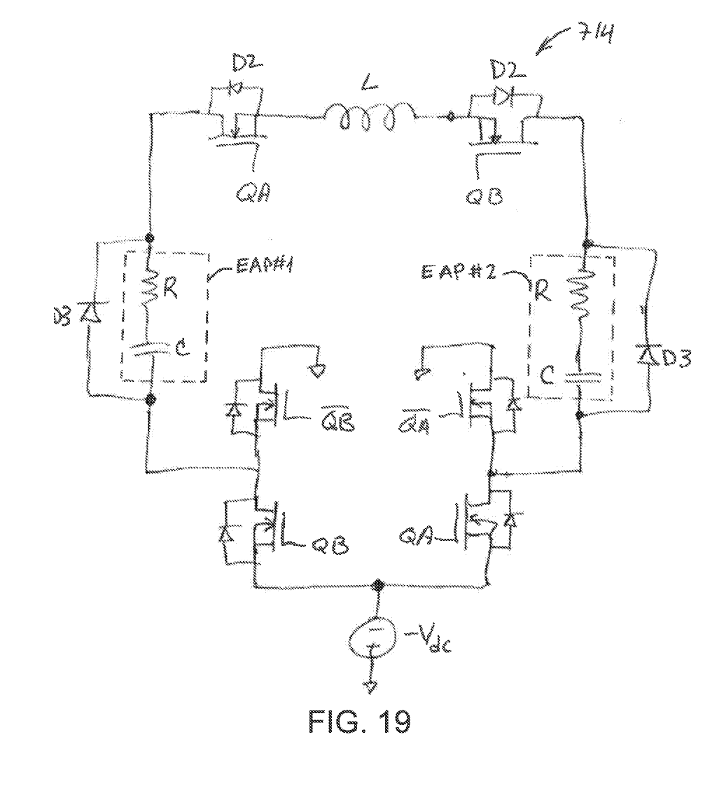

FIG. 19 illustrates a basic schematic diagram variation of a drive circuit 714 for driving a double-diaphragm electroactive polymer actuator, in accordance with one embodiment of the present invention. The circuit 714 is a variation of the circuit 712 shown in FIG. 17. The circuit 714 includes a negative de power supply −V_{dc} rather than a positive dc power supply +V_{dc}. Thus, the diodes in the circuit 714 are reversed relative to the diodes in the circuit 712. The circuit includes a negative de power supply −V_{dc}, six transistor switches labeled QA, QB and Q̅A̅, Q̅B̅. The electroactive polymer (EAP #1) is charged when switches QA and Q̅B̅ are on and switches QB and Q̅A̅ are off. The electroactive polymer (EAP #2) is charged when switches QB and Q̅A̅ are on and switches QA and Q̅B̅ are off.

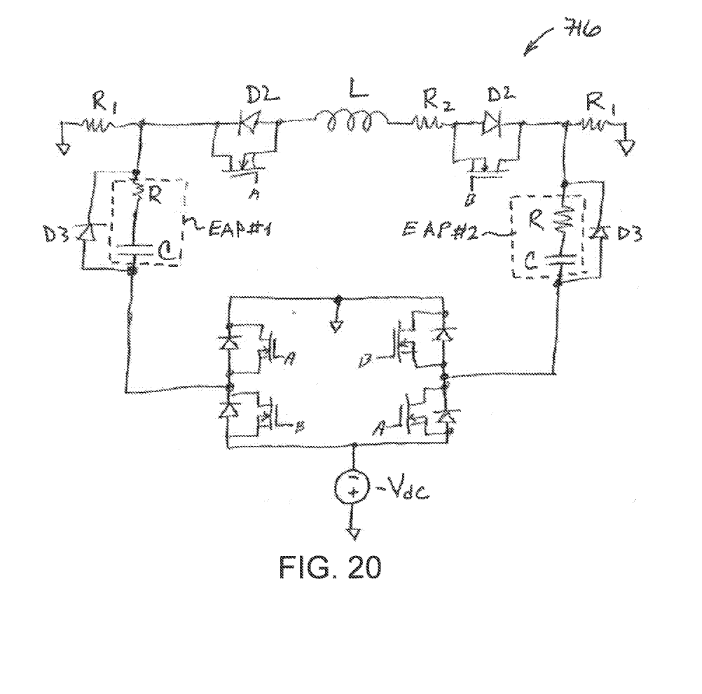

FIG. 20 illustrates a basic schematic diagram variation of a drive circuit 716 for driving a double-diaphragm electroactive polymer actuator, in accordance with one embodiment of the present invention. The circuit 716 is a variation of the circuit 714 shown in FIG. 19 where the electroactive polymers (EAP #1) and (EAP #2) are tied to ground through R₁ (e.g., 100 MΩ) resistors. Also, a resistance R₂ is placed in series with the indictor L. The electroactive polymer (EAP #2) is charged when switches A are on and switches B are off and the electroactive polymer (EAP #1) is charged when switches B are on and switches A are off.

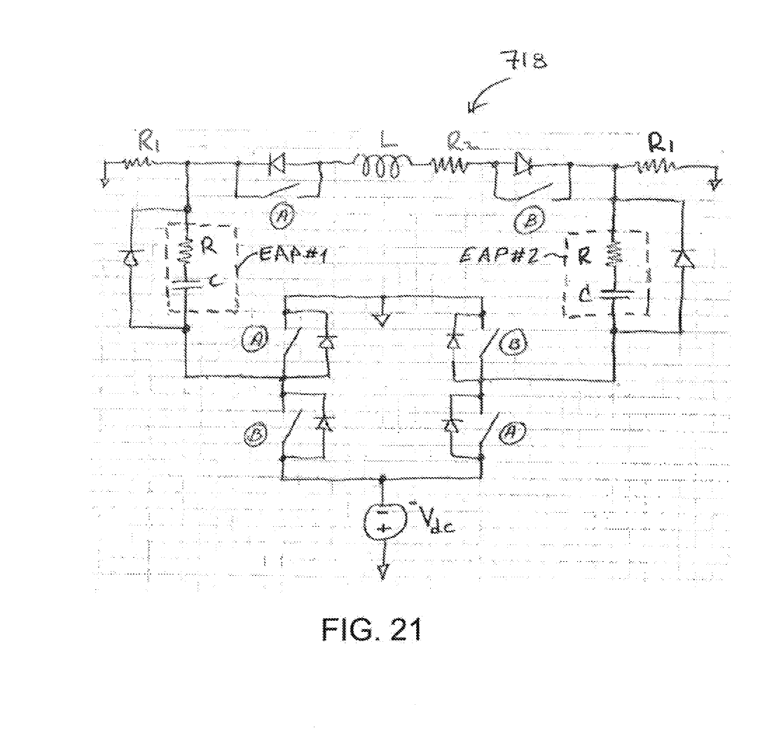

FIG. 21 illustrates a basic schematic diagram variation of a drive circuit 718 for driving a double-diaphragm electroactive polymer actuator, in accordance with one embodiment of the present invention. The circuit 718 is a variation of the circuit 716 shown in FIG. 20 where the solid state transistor switches are shown schematically as single pole-single throw switches to aid understanding of the operation of the circuit. Otherwise, the operation of the circuit 718 is similar to the circuit 716 in that the electroactive polymer (EAP #2) is charged when switches A are on and switches B are off and the electroactive polymer (EAP #1) is charged when switches B are on and switches A are off.

It should be understood that the circuits described herein are not restricted to this actuator configuration. They may be utilized advantageously in other systems where multiple actuators or multiple active regions in a monolithic actuator are driven out of phase from one another.

FIGS. 22A-22C diagrammatically illustrate the geometry and operation of frustum-shaped actuators in accordance with one embodiment. Specifically, FIGS. 22A-22C diagrammatically illustrate the manner in which these concave/convex or frustum shaped actuators function in a simplified two dimensional model. FIG. 22A illustrates the derivation of the transducer frustum shape. Whether conical, squared, ovaloid, etc. when viewed from above, from the side a truncated form 660 is provided by modifying existing diaphragm actuator configurations by capping the top (or bottom) of the structure. When under tension, the cap 642 alters the shape the electroactive polymer layer/layers 610/610′ would take. In the example where a point load stretches the film, the film would assume a conical shape (as indicated by dashed lines define a triangular top 662). However, when capped or altered to form a more rigid top structure, the form is truncated as indicated in solid lines 664 in FIG. 22A. So-modifying the structure fundamentally alters its performance. For one, it distributes stress that would otherwise concentrate at the center of structure 666 around a periphery 668 of the body instead. In order to effect this force distribution, the cap is affixed to the electroactive polymer layers. An adhesive bond may be employed. Alternatively, the constituent pieces may be bonded using any viable technique such as thermal bonding, friction welding, ultrasonic welding, or the constituent pieces may be mechanically locked or clamped together. Furthermore, the capping structure may comprise a portion of the film that is made substantially more rigid through some sort of thermal, mechanical or chemical techniques—such as vulcanizing.

Preferably, the cap section will be sized to produce a perimeter of sufficient length to adequately distribute stress applied to the material. The ratio of size of the cap to the diameter of the frame holding the electroactive polymer layers may vary. Clearly, the size of disc, square, etc. employed for the cap will be larger under higher stress/force application. The relative truncation of the structure (as compared to point-loaded cones, pressure biased domes, etc.) is of further importance to reduce the aggregate volume or space the transducer occupies in use, for a given amount of pre-stretch to the electroactive polymer layers. Furthermore, in a frustum type diaphragm actuator, the cap or diaphragm 642 element may serve as an active component (such as a valve seat, etc. in a given system).

With the more rigid cap section formed or set in place, when the electroactive polymer material housed by a frame is stretched in a direction perpendicular to the cap, it produces the truncated form. Otherwise, the electroactive polymer film remains substantially flat or planar.

Still with reference to FIG. 22A, with the cap 642 defining a stable top/bottom surface, the attached electroactive polymer sides 610/610′ of the structure assume an angle. The angle α of the electroactive polymer is set at when not activated preferably may range between 15 and about 85 degrees. More preferably, it will range from about 30 to about 60 degrees. When voltage is applied, so that the electroactive polymer material is compressed and grows in its planar dimensions, it assumes a second angle β in about the same range plus between about 5 and 15 degrees. Optimum angles may be determined based on application specifications.

Single-sided frustum transducers are within the contemplated scope of the present invention as well as double-sided structures. For preload, single-sided devices employ any of a spring interfacing with the cap (e.g., a coil, a constant force or roll spring, leaf spring, etc.), air or fluid pressure, magnetic attraction, a weight (so that gravity provides preload to the system), or a combination of any of these means or others.

In double-sided frustum transducers, one side preferably provides preload to the other. Still, such devices may include additional bias features/members. FIG. 22B illustrates the basic “double-frustum” architecture 670. Here, opposing layers of electroactive polymer material or one side of electroactive polymer film and one side of basic elastic polymer are held together under tension along an interface section 627. The interface section often comprises one or more rigid or semi-rigid cap element(s) 642. However, by adhering two layers of the polymer together at their interface, the combined region of material, alone, offers a relatively stiffer or less flexible cap region in the most basic manner to offer a stable interface portion of the transducer.

However constructed, the double-frustum transducer operates as shown in FIG. 22C. When one film side 674 is energized, it relaxes and pulls with less force, releasing stored elastic energy in the bias side 674 and doing work through force and stroke. Such action is indicated by dashed line in FIG. 22C. If both film elements comprise electroactive polymer film, then the actuator can move in/out or up/down relative to a neutral position (shown by solid line in each of FIGS. 22A and 2.2B) as indicated by double-headed arrow 680.

If only one active side 674/676 is provided, forced motion is limited to one side of neutral position 682. In which case, the non-active side of the device may simply comprise a spring or an elastic polymer to provide preload/bias (as mentioned above) or electroactive polymer material that is connected electrically to sense change in capacitance only or to serve as a generator to recover motion or vibration input in the device in a regenerative capacity.

Additional optional variations for transducers according to the present invention include provision for multi-angle/axis sensing or actuation. FIG. 23 is a top view of a multi-phase frustum-shaped actuator in accordance with one embodiment. FIG. 23 shows a circular electroactive polymer cartridge 690 configuration with three (692, 694, 696) independently addressable zones or phases. When configured as an actuator, by differential voltage application, the sections will expand differently causing cap 642 to tilt on an angle. Such a multi-phase device can provide multi-directional tilt as well as translation depending on the manner of control. When configured for sensing, input from a rod or other fastener or attachment to the cap causing angular deflection can be measured by way of material capacitance change.

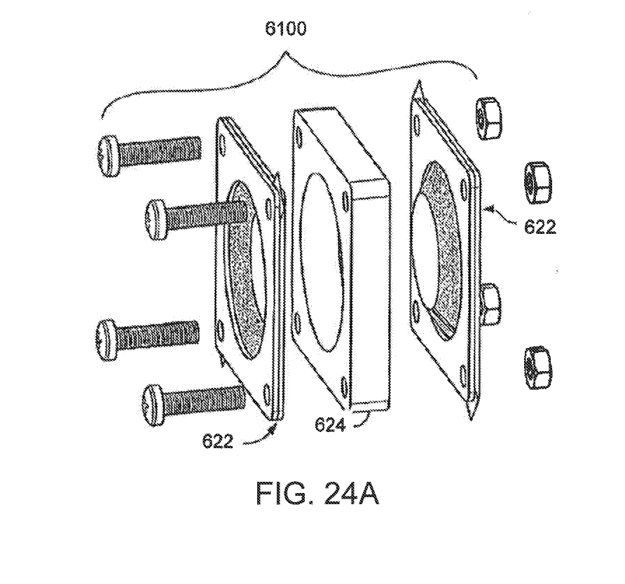

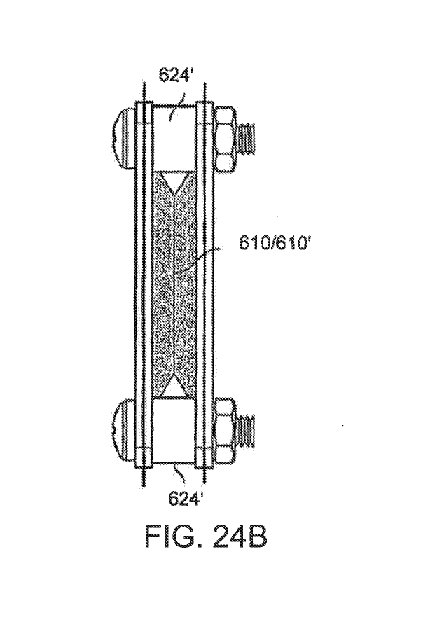

The electroactive polymer section shown in Ha 23 is round. FIG. 24A is an assembly view of another frustum shaped actuator, and FIG. 24B is a side view the same basic actuator with an alternate frame construction in accordance with one embodiment. FIG. 24A provides an assembly view of a round-frustum transducer 6100. The body frame member 624 employed is solid, resembling that used in the combination or convertible type actuator. However, the device shown in FIG. 24A is a dedicated diaphragm type actuator (though it may employ a multiphase structure shown in FIG. 23). An alternative construction for such an actuator is shown in FIG. 24B. Here, the monolithic frame element 624 is replaced by simple frame spacers 624′.

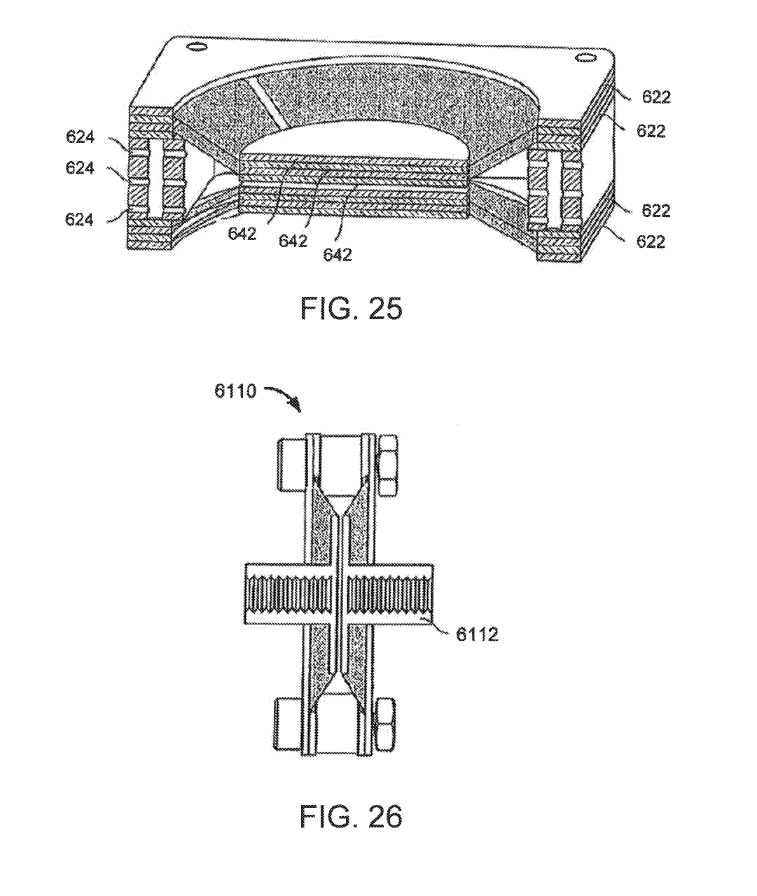

FIG. 25 is a sectional perspective view of a parallel-stacked type of frustum transducer in accordance with one embodiment. FIG. 25 shows another construction variation in which the transducer comprises multiple cartridge layers 622 on each side of a double-frustum device 6100. Individual caps 642 are ganged or stacked together. To accommodate the increased thickness, multiple frame sections 624 may likewise be stacked upon one another.

Each cartridge 622 may employ compound electroactive polymer layers 10. Either one or both approaches—together—may be employed to increase the output potential of the subject device. Alternatively, at least one cartridge member in the stack (on either one or both sides of the device) may be setup for sensing as opposed to actuation to facilitate active actuator control or operation verification. Regarding such control, any type of feedback approach such as a PI (proportional-integral) or PID (proportional-integral-derivative) controller may be employed in such a system to control actuator position with very high accuracy and/or precision.

FIG. 26 is a side-section view showing an optional output shaft arrangement with a frustum type transducer in accordance with one embodiment. FIG. 26 is a side-section view showing an optional output shaft arrangement with a frustum type transducer 6110. Threaded bosses 6112 on either side of the cap pieces provide a means of connection for mechanical output. The bosses may be separate elements attached to the cap(s) or may be formed integral therewith. Although an internal thread arrangement is shown, an external threaded shaft may be employed. Such an arrangement may comprise a single shaft running through the cap(s) and secured on either side with a nuts in a typical jam-nut arrangement. Other fastener or connection options are possible as well.

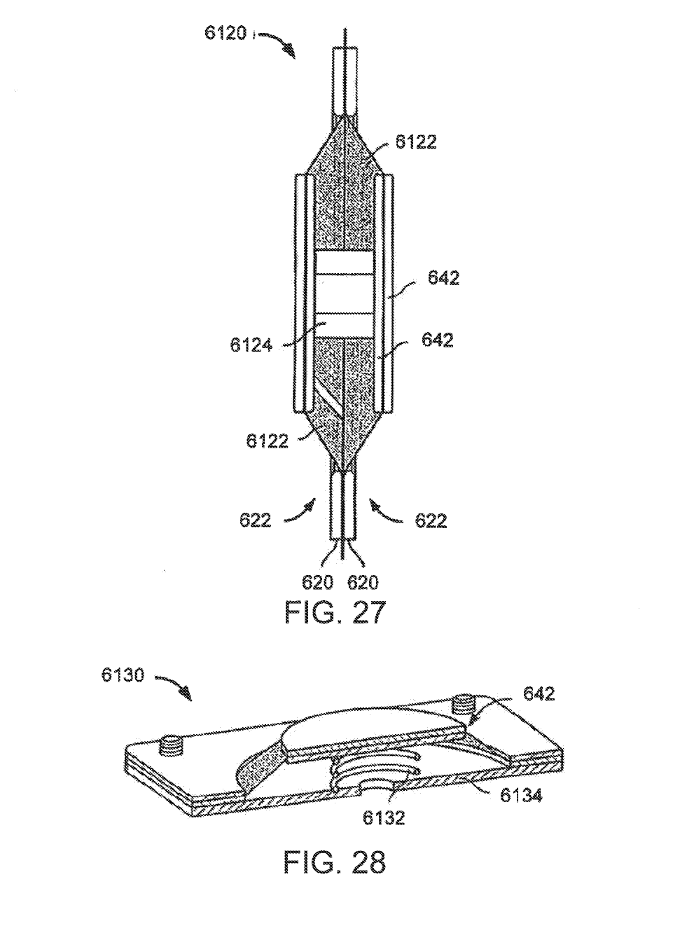

FIG. 27 is a side-section view of an alternate, inverted frustum transducer configuration in accordance with one embodiment. FIG. 27 is a side-section view of an alternate transducer 6120 configuration, in which instead of employing two concave structures facing away from one another, the two concave/frustum sections 6122 face towards each other. The preload or bias on the electroactive polymer layers to force the film into shape is maintained by a shim or spacer 6124 between caps 642. As shown, the space comprises an annular body. Note also that the inward-facing variation of the invention in FIG. 27 does not require an intermediate frame member 6124 between individual cartridge sections 622. Indeed, the electroactive polymer layers on each side of the device can contact one another. Thus, in situations where mounting space is limited, this variation of the invention may offer benefits. Further uses of this device configuration are also discussed below. Other biasing approaches for frustum-type actuators are, however, first described.

FIG. 28 is a sectional perspective view of a coil spring-biased single frustum transducer in accordance with one embodiment. Specifically, FIG. 28 provides a sectional perspective view of a coil spring-biased single frustum transducer 6130. Here, a coil spring 6132 interposed between cap 642 and a baffle wall 6134 associated with the frame (or part of the frame itself) biases the electroactive polymer structure.

It is to be appreciated that the embodiments described herein illustrate example implementations, and that the functional elements, logical blocks, program modules, and circuits elements may be implemented in various other ways which are consistent with the described embodiments. Furthermore, the operations performed by such functional elements, logical blocks, program modules, and circuits elements may be combined and/or separated for a given implementation and may be performed by a greater number or fewer number of components or program modules. As will be apparent to those of skill in the art upon reading the present disclosure, each of the individual embodiments described and illustrated herein has discrete components and features which may be readily separated from or combined with the features of any of the other several embodiments without departing from the scope of the present disclosure. Any recited method can be carried out in the order of events recited or in any other order which is logically possible.

Groupings of alternative elements or embodiments disclosed herein are not to be construed as limitations. Each group member may be referred to and claimed individually or in any combination with other members of the group or other elements found herein. It is anticipated that one or more members of a group may be included in, or deleted from, a group for reasons of convenience and/or patentability.

Various aspects of the subject matter described herein are set out in the following numbered clauses:

1. A thermal management apparatus comprising: a housing defining a first air flow channel and a second air flow channel; an electroactive polymer actuator located within the housing, the electroactive polymer actuator configured to move in response to an activation signal; wherein the electroactive polymer actuator defines a first chamber in fluid communication with the first air flow channel and defines a second chamber in fluid communication with the second air flow channel, the first and second chambers fluidically isolated from each other; and wherein the electroactive polymer actuator is configured to oscillate when excited by the activation signal and eject pulses of air through the first and second air flow channels.

2. The thermal management apparatus according to clause 1, wherein the electroactive polymer actuator comprises: a first diaphragm comprising a first electroactive polymer film; and a second diaphragm comprising a second electroactive polymer film, wherein the first and second diaphragms are oriented adjacent to each other and are connected at a portion thereof; and wherein each of the first and second diaphragms is configured to move in response to an activation signal being applied to each of the first and second electroactive polymer films.

3. The thermal management apparatus according to clause 2, wherein a first surface of the first diaphragm forms a portion of the first chamber and a first surface of the second diaphragm forms a portion of the second chamber.

4. The thermal management apparatus according to clause 2, wherein a second surface of the first diaphragm and a second surface of the second diaphragms forms a third chamber fluidically isolated form the first and second chambers.

5. The thermal management apparatus according to any one of clauses 2 to 4, wherein the first electroactive polymer film is excited by a first activation signal and the second electroactive polymer film is excited by a second activation signal.

6. The thermal management apparatus according to clause 5, wherein the first and second activation signals are 180° out of phase.

7. The thermal management apparatus according to any one of Claims 2 to 6, wherein the first and second diaphragms are biased away from each other.

8. The thermal management apparatus according to any one of Claims 1 to 7, further comprising a mass attached to the electroactive polymer actuator.

9. The thermal management apparatus according to any one of Claims 1 to 8, wherein the apparatus has a series resistance greater than 1000 ohms.

10. The thermal management apparatus according to any one of Claims 1 to 9, wherein the apparatus operates at voltages greater than 200 volts.

11. The thermal management apparatus according to any one of Claims 1 to 10, wherein the apparatus has an operating frequency less than 1000 Hz.

12. A method of generating air flow in a thermal management apparatus comprising a housing that defines a first air flow channel and a second air flow channel, an electroactive polymer actuator located within the housing, the electroactive polymer actuator configured to move in response to an activation signal, wherein the electroactive polymer actuator defines a first chamber in fluid communication with the first air flow channel and defines a second chamber in fluid communication with the second air flow channel, the first and second chambers are fluidically isolated from each other, and wherein the electroactive polymer actuator is configured to oscillate when excited by the activation signal and eject pulses of air through the first and second air flow channels, the method comprising: applying a first excitation voltage to the electroactive polymer actuator; applying a second excitation voltage to the electroactive polymer actuator that is 180° out of phase with the first excitation voltage; and oscillating the electroactive polymer actuator within the housing in response to the first and second excitation voltages.

13. The method according to Claim 12, further comprising: ejecting a pulse of air from the first chamber; and drawing in a pulse of air in the second chamber, when the electroactive polymer is deflected in a first direction towards the first chamber and away from the second chamber in response to the first and second excitation voltages.

14. The method according to one of Claims 12 and 13, further comprising: inverting the phase of the first and second excitation voltages; ejecting a pulse of air from the second chamber; and drawing in a pulse of air in the first chamber, when the electroactive polymer is deflected in a second direction towards the second chamber and away from the first chamber in response to the inverted first and second excitation voltages.

15. The method according to Claim 12, comprising: repeating:
inverting the phase of the first and second excitation voltages; ejecting a pulse of air from the first chamber; and drawing in a pulse of air in the second chamber, when the electroactive polymer is deflected in a first direction towards the first chamber and away from the second chamber in response to the first and second excitation voltages; inverting the phase of the first and second excitation voltages; ejecting a pulse of air from the second chamber; and drawing in a pulse of air in the first chamber, when the electroactive polymer is deflected in a second direction towards the second chamber and away from the first chamber in response to the inverted first and second excitation voltages.

16. A method of driving an energy-efficient electroactive polymer actuator comprising at least a first and second pair of opposing compliant electrodes sandwiching a dielectric electroactive polymer film, the method comprising: applying a first excitation voltage to the first pair of electrodes on the electroactive polymer actuator; and applying a second excitation voltage to the second pair of electrodes on the electroactive polymer actuator that is 180° out of phase with the first excitation voltage; wherein at least a portion of charge obtained by discharging the first excitation voltage is applied during the second excitation voltage.

17. The method according to Claim 16, wherein the frequency and/or duty cycle is varied to alter the performance parameters of the apparatus.

18. The method according to Claim 16, wherein the electrical charge is varied to alter the performance parameters of the apparatus.

19. The method according to Claim 16, wherein three or more polymer actuators are operated sequentially.

1. A thermal management apparatus comprising:
a housing defining a first air flow channel and a second air flow channel;
an electroactive polymer actuator located within the housing, the electroactive polymer actuator configured to move in response to an activation signal;
wherein the electroactive polymer actuator defines a first chamber in fluid communication with the first air flow channel and defines a second chamber in fluid communication with the second air flow channel, the first and second chambers fluidically isolated from each other; and
wherein the electroactive polymer actuator is configured to oscillate when excited by the activation signal and eject pulses of air through the first and second air flow channels.

2. The thermal management apparatus according to claim 1, wherein the electroactive polymer actuator comprises:
a first diaphragm comprising a first electroactive polymer film; and
a second diaphragm comprising a second electroactive polymer film,
wherein the first and second diaphragms are oriented adjacent to each other and are connected at a portion thereof; and wherein each of the first and second diaphragms is configured to move in response to an activation signal being applied to each of the first and second electroactive polymer films.

3. The thermal management apparatus according to claim 2, wherein a first surface of the first diaphragm forms a portion of the first chamber and a first surface of the second diaphragm forms a portion of the second chamber.

4. The thermal management apparatus according to claim 2, wherein a second surface of the first diaphragm and a second surface of the second diaphragms forms a third chamber fluidically isolated form the first and second chambers.

5. The thermal management apparatus according to claim 2, wherein the first electroactive polymer film is excited by a first activation signal and the second electroactive polymer film is excited by a second activation signal.

6. The thermal management apparatus according to claim 5, wherein the first and second activation signals are 180° out of phase.

7. The thermal management apparatus according to claim 2, wherein the first and second diaphragms are biased away from each other.

8. The thermal management apparatus according to claim 1, further comprising a mass attached to the electroactive polymer actuator.

9. The thermal management apparatus according to claim 1, wherein the apparatus has a series resistance greater than 1000 ohms.

10. The thermal management apparatus according to claim 1, wherein the apparatus operates at voltages greater than 200 volts.

11. The thermal management apparatus according to claim 1, wherein the apparatus has an operating frequency less than 1000 Hz.

12. A method of generating air flow in a thermal management apparatus comprising a housing that defines a first air flow channel and a second air flow channel, an electroactive polymer actuator located within the housing, the electroactive polymer actuator configured to move in response to an activation signal, wherein the electroactive polymer actuator defines a first chamber in fluid communication with the first air flow channel and defines a second chamber in fluid communication with the second air flow channel, the first and second chambers are fluidically isolated from each other, and wherein the electroactive polymer actuator is configured to oscillate when excited by the activation signal and eject pulses of air through the first and second air flow channels, the method comprising:
applying a first excitation voltage to the electroactive polymer actuator;
applying a second excitation voltage to the electroactive polymer actuator that is 180° out of phase with the first excitation voltage; and
oscillating the electroactive polymer actuator within the housing in response to the first and second excitation voltages.

13. The method according to claim 12, further comprising:
ejecting a pulse of air from the first chamber; and
drawing in a pulse of air in the second chamber, when the electroactive polymer is deflected in a first direction towards the first chamber and away from the second chamber in response to the first and second excitation voltages.

14. The method according to claim 12, further comprising:
inverting the phase of the first and second excitation voltages;
ejecting a pulse of air from the second chamber; and
drawing in a pulse of air in the first chamber, when the electroactive polymer is deflected in a second direction towards the second chamber and away from the first chamber in response to the inverted first and second excitation voltages.

15. The method according to claim 12, comprising:
repeating:
inverting the phase of the first and second excitation voltages;
ejecting a pulse of air from the first chamber; and
drawing in a pulse of air in the second chamber, when the electroactive polymer is deflected in a first direction towards the first chamber and away from the second chamber in response to the first and second excitation voltages;
inverting the phase of the first and second excitation voltages;
ejecting a pulse of air from the second chamber; and
drawing in a pulse of air in the first chamber, when the electroactive polymer is deflected in a second direction towards the second chamber and away from the first chamber in response to the inverted first and second excitation voltages.

16. A method of driving an energy-efficient electroactive polymer actuator comprising at least a first and second pair of opposing compliant electrodes sandwiching a dielectric electroactive polymer film, the method comprising:
applying a first excitation voltage to the first pair of electrodes on the electroactive polymer actuator; and
applying a second excitation voltage to the second pair of electrodes on the electroactive polymer actuator that is 180° out of phase with the first excitation voltage;
wherein at least a portion of charge obtained by discharging the first excitation voltage is applied during the second excitation voltage.

17. The method according to claim 16, wherein the frequency and/or duty cycle is varied to alter the performance parameters of the apparatus.

18. The method according to claim 16, wherein the electrical charge is varied to alter the performance parameters of the apparatus.

19. The method according to claim 16, wherein three or more polymer actuators are operated sequentially.
